(19) United States
(12) Patent Application Publication
(10) Pub. No.: US 2008/0054894 A1
(43) Pub. Date: Mar. 6, 2008

(54) MAGNETIC DETECTION DEVICE HAVING ELEMENT PROVIDED WITH MULTI-LAYERED PROTECTION LAYER AND A METHOD OF MANUFACTURING THE SAME

(75) Inventors: Toshio Sasaki, Niigata-ken (JP); Kiyoshi Sato, Niigata-ken (JP); Ichiro Tokunaga, Niigata-ken (JP)

Correspondence Address: BRINKS HOFER GILSON & LIONE, P.O. BOX 10395, CHICAGO, IL, 60610, US

(73) Assignee: ALPS ELECTRIC CO., LTD., Tokyo (JP)

(21) Appl. No.: 11/678,812

(22) Filed: Feb. 26, 2007

(30) Foreign Application Priority Data
Sep. 4, 2006 (JP) 2006-239188

(51) Int. Cl. G01R 33/02

(52) U.S. Cl. 324/252

(57) ABSTRACT

The invention provides a magnetic detection device having excellent thermal resistance and water resistance by changing a configuration of layers of an insulating protection layer covering a magnetic detection element. A magnetic detection element is covered with an insulating protection layer, and the insulating protection layer has an alumina layer covering the magnet detection element and a silica layer covering the alumina layer. According to the embodiment, thermal resistance and water resistance can be properly improved, and therefore a magnetic detection device having excellent magnetic sensitivity and a high reliability can be realized without degrading characteristics of the magnetic detection device.

This application claims the benefit of priority under 35 U.S.C. § 119 to Japanese Patent Application No. 2006-239188, filed Sep. 4, 2006, which is hereby incorporated by reference in its entirety.

### BACKGROUND OF THE INVENTION

1. Field of the Invention

The invention relates to a magnetic detection device having a magnetic field detection element, which detects an exterior magnetic field by using an anisotropic magnetoresistance effect (AMR effect), a giant magnetoresistance effect (GMR effect), or a tunnel magnetoresistance effect (TMR effect), and a detection circuit which detects a change in potential based on an electrical resistance of the magnetic detection element, and a method of manufacturing the magnetic detection device.

2. Description of the Related Art

A magnetic detection device that detects an exterior magnetic field is used as a non-contact ON-OFF switch, a circular encoder detecting a rotation phase or a rotation number, or the like. A known type of magnetic detection device mainly uses a hall element as a magnetic detection element. However, the magnetic detection device using the hall element requires a correction circuit for correcting a detected output, and thus has a drawback that a circuit configuration of the magnetic detection circuit becomes complicated. In this respect, a magnetic detection element using a magnetoresistance effect has an advantage that it is relatively simple to configure the detection circuit and it is possible to detect the exterior magnetic field with a high precision.

In the magnetic detection device, a plurality of groups of the magnetic detection elements using the magnetoresistance effect and the detection circuit are formed on a substrate, and then the substrate is diced into the groups to obtain respective chips. Then, the chips are packaged to final products.

JP-A-2004-327651 is an example of related art.

In the above-mentioned manufacturing process, the magnetic detection element is covered with an insulating protection layer in order to prevent the magnetic detection element from being exposed to an outside environment.

In the related art, a silica (SiO2) layer is used in the insulating protection layer. However, when the silica layer is used in the insulating protection layer, it is likely that the magnetic detection element is subjected to oxidation in the heat environment since oxygen in the atmosphere permeates and a resistance value of the magnetic detection element increases. Since a magnetic sensitivity is degraded by the change in a resistance of the magnetic detection element, it is required that the nearly constant resistance value is maintained in the magnetic detection element in a state that the exterior magnetic field is not applied.

Meanwhile, when the alumina (Al₂O₃) layer is used instead of the silica layer, a thermal resistance of the magnetic detection element can be improved, but a water resistance thereof is deteriorated. That is, water dissolves the alumina layer, thereby not properly protecting the magnetic detection element from the outside environment. During the manufacturing process, water is used as cooling water to cool the frictional heat, particularly when the substrate is diced. Accordingly, it is required that magnetic detection element is covered with an insulating protection layer with a high water resistance.

Additionally, since the magnetic detection device is incorporated in small-sized electronic apparatuses such as a mobile phone, it is required that the insulating protection layer that covers the magnetic detection element is configured to have layers as small as possible while having an excellent thermal resistance and water resistance. In this manner, small-sized magnetic detection device can be realized.

### SUMMARY OF THE INVENTION

The present invention provides a high-reliable magnetic detection device with excellent water resistance and thermal resistance, by properly changing a configuration of an insulating protection layer covering the magnetic detection element.

Additionally, the invention provides a method of manufacturing the magnetic detection device capable of properly and easily preventing a characteristic of a magnetic detection element from being degraded due to excellent water resistance and thermal resistance of the insulating protection layer even when the magnetic detection element undergoes heating treatment during the manufacture process or is exposed to cooling water used during the dicing process.

According to an aspect of the invention, the magnetic detection device includes a substrate, a sensor section including a magnetic detection element using a magnetoresistance effect in which an electrical resistance varies in accordance with an exterior magnetic field, and a detection circuit connected to the sensor section to detect a variation in potential based on the variation in the electrical resistance of the magnetic detection element. The sensor section and the detection circuit being formed on the substrate, wherein the magnetic detection element is covered with an insulating protection layer which has an alumina layer (Al₂O₃) covering the magnetic detection element and a silica layer (SiO₂) covering the alumina layer.

The insulating protection layer covering the magnetic detection element has two-layered structure of the alumina layer and the silica layer formed on the alumina layer. The alumina layer may improve the thermal resistance and may be covered with the silica layer in order to protect the poor water-resistant alumina layer. Further, it is not desirable that the silica layer and the alumina layer are reversely laminated. In this case, the uppermost layer of the insulating protection layer is the alumina layer, but since the alumina layer is poor in the thermal resistance, the alumina layer may be dissolved by water during the dicing process. Accordingly, since the poor thermal resistant silica layer may be exposed, the magnetic detection element may be affected by oxygen and be subject to oxidation. As a result, the insulating protection layer in which the silica layer and the alumina layer are sequentially laminated from the bottom cannot achieve the advantage of the invention. However, by covering the magnetic detection element with the alumina layer and covering the alumina layer with the silica layer in the invention, the high-reliable magnetic detection device with both the excellent thermal resistance and water resistance may be realized, even thought the magnetic detection device has a thin-layered configuration.

The sensor section may be connected in series to the magnetic detection element and may have a fixed resistance element in which the electrical resistance does not vary in accordance with the exterior magnetic field. The fixed resistance element may be also covered with the insulating protection layer.

The insulating protection layer may cover a conductive connection layer which connects either or both of the magnetic detection element and the fixed resistance element to the detection circuit.

In this manner, the fixed resistance element and the connection layer have good thermal resistance and water resistance, and more effectively, the stable and high-reliable magnetic detection device may be realized.

The detection circuit may be formed on the substrate. The detection circuit may be covered with an insulating layer, and the sensor section is formed on the insulating layer, and the sensor section formed on the insulating layer and the detection circuit formed on the substrate may be conductively connected to each other. Accordingly, the magnetic detection device may decrease in size and both the detection circuit and the sensor section may be properly protected and insulated.

According to another aspect of the invention, there is provided a method of manufacturing a magnetic detection device which has a sensor section including a magnetic detection element using a magnetoresistance effect in which an electrical resistance varies in accordance with an exterior magnetic field. The detection circuit is connected to the sensor section to detect a variation in potential based on the variation in the electrical resistance of the magnetic detection element to be formed on the substrate. The method includes the steps of (a) forming a plurality of groups of the detection circuits and the sensor sections on the substrate, (b) covering the magnetic detection elements with an alumina (Al₂O₃) layer and covering the alumina layer with a silica (SiO₂) layer, (c) dicing the substrate into groups in a state where the silica layer is exposed, while spraying cooling water, thereby obtaining individual chips of the magnetic detection device, and (d) packaging each of the chips of the magnetic detection devices.

In the step of (b), the thermal resistance may be improved by forming the alumina layer on the magnetic detection element. On the other hand, when the alumina layer is an uppermost surface of the insulating protection layer and is exposed, the cooling water used during the dicing process in the step of (c) may dissolve the alumina layer. Accordingly, in order to protect the alumina layer in the step of (b), the silica layer with the good water resistance may be formed on the alumina layer.

In this manner, even when the heat treatment process is performed, the variation in the resistance value due to the oxidation of the magnetic detection element may be properly suppressed without oxidation of the magnetic detection element. Further, even when the cooling water is used during the dicing process in the step of (c), the insulating protection layer may be properly prevented from erosion and dissolution.

Even when the insulating protection layer has two-layered structure of the alumina layer and silica layer, and the dicing process or the heat treatment process are performed in a state the silica layer is exposed in the step of (c), the stable magnetic detection device may be properly manufactured without degrading the water resistance and thermal resistance. In this manner, manufacturing the insulating protection layer may be simple and the small-sized magnetic detection device may be achieved due to two-layer structure of the insulating protection layer.

The step of (a) may include (a-1) forming the plurality of groups of the detection circuits on the substrate, (a-2) covering the detection circuits with an insulating layer, and (a-3) forming the plurality of groups of the sensor section on the insulating layer to conductively connect each sensor section and each detection circuit to each other.

In this manner, the small-sized magnetic detection device may be realized and both the detection circuit and the sensor section may be properly protected to be insulated.

The sensor section may be connected in series to the magnetic detection element and has a fixed resistance element in which an electrical resistance does not vary in accordance with an exterior magnetic field. The fixed resistance element may be covered with the alumina layer and the alumina layer is covered with the silica layer in the step of (b).

Additionally, a conductive connection layer which connects either or both the magnetic detection element and the fixed resistance element to the detection circuit may be covered with the alumina layer and the alumina layer may be covered with the silica layer in the step of (b).

In this manner, the fixed resistance element and the connection layer with an excellent thermal resistance and water resistance may be formed, and thus more effectively, the stable magnetic detection device may be manufactured.

In the invention, by covering the magnetic detection element with the alumina layer and covering the alumina layer with the silica layer, the high-reliable magnetic detection device with an excellent thermal resistance and water resistance may be achieved even though the magnetic detection device has a small-layered configuration.

Even when the insulating protection layer covering the magnetic detection element has two-layered structure of the alumina layer and silica layer, and the dicing and heat treatment processes are performed, the stable magnetic detection device may be properly manufactured without degrading the water resistance and thermal resistance. In this manner, due to two-layered structure of the insulating protection layer, manufacturing the insulating protection layer may be simple, and the small-sized magnetic detection device may be realized.

### BRIEF DESCRIPTION OF THE DRAWING

FIG. 1 is a schematic diagram illustrating a magnetic detection device according to embodiments of the invention.

FIG. 2 is a vertical sectional view taken along the line II-II of FIG. 1 illustrating a magnetic detection device according to a first embodiment of the invention.

FIGS. 3A to 3E are process diagrams illustrating processes of manufacturing the magnetic detection device according to embodiments of the invention, where each diagram is a vertical sectional view like FIG. 2.

FIG. 4 is a schematic diagram of a dicing process.

FIG. 5 is a graph showing a relation between time lapsed and variation ratio of resistance of a magnetic detection element when a heat treatment was performed at 200° C. to the magnetic detection element provided with an insulating protection layer of Example 1 and Comparative Examples 1 and 2.

### DESCRIPTION OF THE PREFERRED EMBODIMENTS

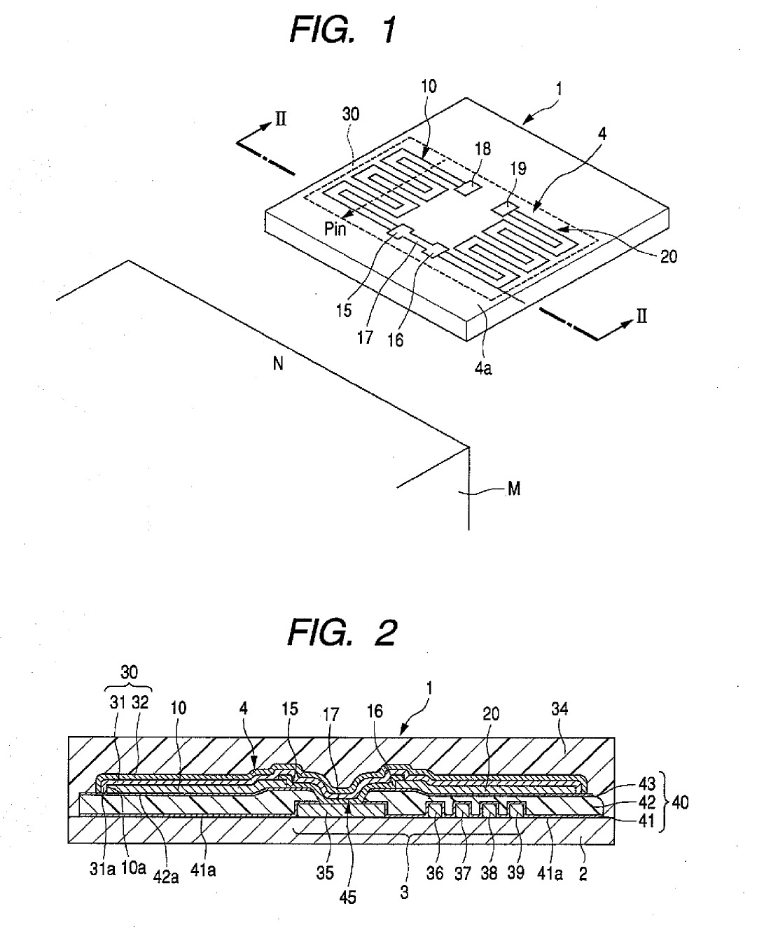

FIG. 1 is a schematic diagram illustrating a magnetic detection device according the embodiment, and FIG. 2 is a vertical sectional view taken along the line II-II of FIG. 1.

A magnetic detection device 1 illustrated in FIG. 1 is an IC package in which a magnetic detection element 10, a fixed resistor element 20, and a detection circuit are integrated together, and is configured to have a small and thin profile.

When a magnetic field-generating member, such as a magnet M approaches, the magnetic detection device 1 can obtain, for example, a pulsed ON output. For example, the magnetic detection device 1 is built in a main section of a foldable cellular phone in which key switches are arranged. When the magnet M is mounted in a foldable section with a display screen, such as a liquid crystal device, and the main section and the foldable section are folded to each other, the magnet M approaches the magnetic detection device 1. In this case, a magnetic field emitted from the magnet M is detected by the magnetic detection device 1, and thus the ON output is obtained from the magnetic detection device 1.

The magnetic detection device 1 is not necessarily incorporated in the mobile phone, but the magnetic detection device 1 can be suitably incorporated in small-sized electronic devices since the magnetic detection device 1 according to the embodiment can be more suitably realized in a small profile.

By using a magnetoresistance effect an electrical resistance of the magnetic detection element 10 varies in accordance with an exterior magnetic field. The fixed resistance element 20 practically has the same electrical resistance and temperature coefficient as the magnetic detection element 10, but the electrical resistance thereof does not vary in accordance with the magnitude of the exterior magnetic field to which the magnetic detection element 10 responds.

The magnetic detection element 10 detects the exterior magnetic field by using a giant magnetoresistance effect (GMR effect). The magnetic detection element 10 has a basic structure in which an antiferromagnetic layer, a fixed magnetic layer, a non-magnetic layer and a free layer are sequentially laminated from the bottom, or vice versa. The antiferromagnetic layer is formed of an Ir—Mn alloy (iridium-manganese alloy), a Pt—Mn alloy (platinum-manganese alloy), or the like. The fixed magnetic layer or free layer are formed of the Co—Fe alloy (cobalt-ferrum alloy), a Ni—Fe alloy (nickel-ferrum alloy), or the like. The non-magnetic layer is formed of a non-magnetic conductive material such as Cu (cuprum). In addition, the magnetic detection element 10 is formed of a protection layer, a foundation layer, or the like.

It is desirable that the fixed resistance element 20 has the same layers as the magnetic detection element 10. That is, the fixed resistance element 20 has an antiferromagnetic layer, a fixed magnetic layer, a non-magnetic layer and a free layer, like the magnetic detection element 10. However, the fixed resistance element 20, for example, is sequentially laminated of the antiferromagnetic layer, the fixed magnetic layer, the free magnetic layer, and the non-magnetic layer from the bottom, or vice versa in a manner different from the magnetic detection element 10. The free magnetic layer constituting the fixed resistance element 20 becomes a magnetic layer of which a magnetization direction is fixed in company with the fixed magnetic layer. As a result, the resistance value of the free magnetic layer does not vary in accordance with a change in the exterior magnetic field (that is, it is no longer a free magnetic layer). Further, it is desirable that each layer constituting the fixed resistance element 20 is formed of the same material and film thickness as each layer constituting the magnetic detection element 10, in that an irregularity of the temperature coefficient of resistance (TCR) can be suppressed.

The magnetic detection element 10 can be also formed as an AMR element using the anisotropic magnetoresistance effect or a TMR element using the tunnel magnetoresistance effect as well as a GMR element.

As shown in FIG. 1, the magnetic detection element 10 and the fixed resistance element 20 are formed in a serpentine or meandering pattern in top plan view, thereby having a high electrical resistance value. By forming the magnetic detection element 10 and the fixed resistance element 20 in the meandering pattern, the current consumption can be lowered. The fixed magnetic layer constituting the magnetic detection element 10 is magnetized and fixed in a pin direction shown in FIG. 1 by an exchange coupling magnetic field of the antiferromagnetic layer. That is, the fixed magnetic layer is fixed in a direction perpendicular to a long direction of the magnetic detection element 10. Accordingly, when the N pole of the magnet M, for example, approaches and the free magnetic layer constituting the magnetic detection element 10 is magnetized in a direction opposite to the pin direction, the electrical resistance value of the magnetic detection element 10 becomes greater. On the other hand, when the magnet M becomes more distant and the exterior magnetization influencing the free magnetic layer disappears, the electrical resistance value thereof becomes weaker.

As shown in FIG. 1, an electrode layer (connection layer) 15 formed of a low resistance material is provided on one edge side of the magnetic detection element 10, and an electrode layer (connection layer) 18 formed of the low resistance material is provided on the other edge side thereof. An electrode layer (connection layer) 16 formed of the low resistance material is provided on one edge side of the fixed resistance element 20 and an electrode layer (connection layer) 19 formed of the low resistance material is provided on other edge side thereof. Additionally, a lead layer (connection layer) 17 connects the electrode layer 15 of the magnetic detection element 10 to the electrode 16 of the fixed resistance element 20, and the magnetic detection element 10 and the fixed resistance element 20 are connected in series each other. The electrode layers and the lead layer are formed of the low resistance material in which gold, silver, copper are used as a main material, and chrome, copper, and chrome, for example, are laminated. Additionally, the electrode layers 15 and 16 and the lead layer 17 are integrally formed.

One of the electrode layers 18 and 19 serves as an input terminal and the other serves as an earth or ground terminal. The lead layer 17 serves as an output terminal. Without application of the exterior magnetic field, the output terminal is placed at a central potential. With application of the exterior magnetic field, the resistance value of the magnetic detection element 10 varies, and a potential of the lead layer 17 varies in accordance with the variation. A detection circuit 3 connected to the lead layer 17 detects the variation in the potential based on the variation in the electrical resistance of the magnetic detection element 10 with respect to the exterior magnetic field, and generates a switching signal, ON-OFF, based of the detection result.

As shown in FIG. 2, a foundation layer made of silica (SiO₂) (not shown) in the magnetic detection device 1 is formed at a regular thickness on the substrate 2 made of silicon (Si), for example.

A wiring layer 35, active elements 36 to 38 and a resistor 39, or the like constituting the detection circuit 3 are formed on the foundation layer. Examples of the active elements 36 to 38 are an integrated circuit (IC), a differential amplifier, a comparator, an output transistor, and the like.

The wiring layer 35 is formed of aluminum (Al), for example. In this manner the wiring layer 35 can be formed as a resistor with a low resistance value, and a wire-bonding process and the like (not shown) can be properly performed.

As shown in FIG. 2, an insulating layer 40, where an insulating lower surface layer 14, a resistor layer 42, and an insulating upper surface layer 43 are sequentially laminated from the bottom, is formed on an area from the wiring layer 35 through the active element 36 to 39, the resistor 39, and the substrate 2.

By forming a hole section 45 of the insulating layer 40 in parts of the wiring layer 35, upper surfaces from the hole section 45 to wiring layer 35 are exposed. The shape of the plan surface of the hole section 45 is not limited to a circular shape, a rectangular shape, and the like, and any suitable shape may be used.

As shown in FIG. 2, the insulating lower surface layer 41 is formed of, for example, silicon nitride (SiN), and is formed on the entire area of the wiring layer 35, the active elements 36 to 38, the resistor 39, and the substrate 2, except for the hole section 45. The insulating lower surface layer 41 is formed, for example, by using the sputter method.

As shown in FIG. 2, the resistor layer (flattened resistor) 42 is formed on the insulating lower surface layer 41. The resistor layer 42 is filled in a concave section formed on the surface of the insulating lower surface layer 41 of the detection circuit 3. A surface 42a of the resistor layer 42 is overall more flat than a surface 41a of the insulating lower surface layer 41. In particular, a surface of the insulating lower surface layer 41 in parts in which the detection circuit 3 is not formed as flat as the surface 42a of the resistor layer 42, but the surface 41a of the insulating lower surface layer 41 in parts in which the detection circuit 3 is formed is less flat than the surface 42a of the resistor layer 42. By overlapping the resistor layer 42 on the insulating lower surface layer 41, a difference between the substrate 2 and the detection circuit 3 covered with the insulating lower surface layer 41 can be at least reduced.

The insulating upper surface layer 43 made of, for example, silicon nitride (SiN) is formed on the resistor layer 42. By providing the insulating upper surface layer 43, an insulating characteristic can be more ensured. It is not required that the insulating upper surface layer 43 is formed.

As shown in FIGS. 1 and 2, the sensor section 4 having the magnetic detection element 10 and the fixed resistance element 20 is formed on the insulating layer 40. The electrode layers 15, 16, 18, and 19 are formed on each edge of the magnetic detection element 10 and the fixed resistance element 20. As shown in FIG. 2, the lead layer 17 connecting the electrode layer 15 of the magnetic detection element 10 to the electrode layer 16 of the fixed resistance element 20, passes through the hole section 45 and extends to an exposed surface of the wiring layer 35 to be formed. In this manner, the magnetic detection element 10 and the fixed resistance element 20 are electrically connected to the wiring layer 35, with the electrode layers 15 and 16 and the lead layer 17 interposed therebetween.

Additionally, the hole section 45 formed on the insulating layer 40 is also formed in a location opposite to the electrode layer 18 of the magnetic detection element 10 and the electrode layer 19 of the fixed resistance element 20, and has a cross section in shape shown in FIG. 2. The magnetic detection element 10 is electrically connected to the wiring layer (not shown) with the electrode layer 18 interposed therebetween, and the fixed resistance element 20 is electrically connected to the wiring layer (not shown) with the electrode layer 19 interposed therebetween.

As shown in FIG. 2, the magnetic detection element 10 is covered with the insulating protection layer 30. As shown in FIG. 2, the insulating protection layer 30 has a two-layered structure of an alumina (Al₂O₃) layer 31 covering the magnetic detection element 10, and a silica (SiO) layer 32 covering the alumina layer 31.

The alumina layer 31 has better thermal resistance than the silica layer 32. In contrast, the silica layer 32 has better water resistance than the alumina layer 31. As shown in FIG. 2, the alumna layer 31 and the silica layer 32 are sequentially laminated from the bottom. That is, when the silica layer 32 and the alumina layer 31 are laminated from the bottom, the thermal resistance and water resistance cannot be properly improved. As described above, the alumina layer 31 is good in the thermal resistance but poor in the water resistance, and when the alumina layer 31 absorbs moisture, the alumina layer 31 is likely to be dissolved. In particular, cooling water used during a dicing process is involved in the dissolution, but as shown in FIG. 2, air passes in the resin 34 and it is easy for water contained in air to erode the alumina layer 31, even in a product packaged by a molded resin 34. At the worst, when the alumina layer 31 is dissolved, the poor thermal resistant silica layer 32 is exposed, and thus air can easily permeate into the magnetic detection element 10. As a result a variation in the resistance value caused by the oxidation of magnetic detection element 10 degrades a characteristic thereof.

Meanwhile, when the insulating protection layer 30 in which the alumina layer 31 and the silica layer 32 are sequentially laminated from the bottom is formed according to the embodiment, the moisture in air and the cooling water used during the dicing process are kept out, and thus cannot permeate into the alumna layer 31. Additionally, since the silica layer 32 has poor thermal resistance, oxygen easily permeates into the silica layer 32 in the heated environment, but the air cannot permeate into the magnetic detection element 10 due to the excellent thermal resistance of the alumina layer 31, thereby properly preventing the magnetic detection element 10 from being oxidized. Accordingly, a constant resistance value of the magnetic detection element 10 can be obtained without the application of the exterior magnetic field.

In this manner, according to the embodiment, the thermal resistance and water resistance can be properly improved, and thus the magnetic detection device 1 with an excellent magnetic sensitivity and high reliability can be realized without degrading the characteristic of the magnetic detection element 10.

The alumina layer 31 completely covers the upper surface and sides of the magnetic detection element 10 such that there is no an exposed part on the magnetic detection element 10. Accordingly, as shown in FIG. 2, the alumina layer 31 even covers a side surface 10a of the magnetic detection element 10. Additionally, the silica layer 32 completely covers the upper surface and sides of the alumina layer 31 such that there is no an exposed part on the alumina layer 31. Accordingly as shown in FIG. 2, the silica layer 32 even covers a side surface 31a of the alumina layer 31.

An average film thickness of the alumina layer 31 and the silica layer 32 is in the range of 50 to 500 nm or so.

As shown in FIG. 1, an area of forming the insulating protection layer 30 covers the fixed resistance element 20 formed on the insulating protection layer 40 and the sensor section 4 including the electrode layers 15, 16, 18, and 19 and the lead layer 17, as well as the magnetic detection element 10. When the detection circuit 3 is partly or wholly exposed on the substrate 2, it is desirable that the detection circuit 3 as well as the sensor section 4 is covered with the insulating protection layer 30. Additionally, the insulating protection layer 30 can be formed on a whole surface of the insulating layer 40 as well as the dotted line area shown in FIG. 1. The insulating protection layer 30 can be divided by forming a pattern.

In this manner, the whole area of the sensor section 4 can be realized to have excellent thermal resistance and water resistance, and more effectively, the magnetic detection device 1 with an excellent magnetic sensitivity and high reliability can be achieved.

As shown in FIG. 2, the detection circuit 3 is formed on the substrate 2, and the detection circuit 3 is covered with the insulating layer 40 to form the sensor section 4 on the insulating layer 40, thereby achieving the small-sized magnetic detection device 1. As shown in FIG. 2, the device can be configured in a smaller area by forming the lead layer 17 on the wiring layer 35 than by forming the wiring layer 35 and the lead layer 17 on a plane surface. The electrode layers 18 and 19 are forming directly on the wiring layer (not shown). By realizing the laminated structure shown in FIG. 2, the detection circuit 3 can be properly protected. Additionally, since the magnetic detection element 10 can be formed on the insulating layer 40 with a flattened shape, the magnetic detection element 10 can be formed with a high precision, thereby realizing the magnetic detection device 1 with a small size and high-magnetic sensitivity.

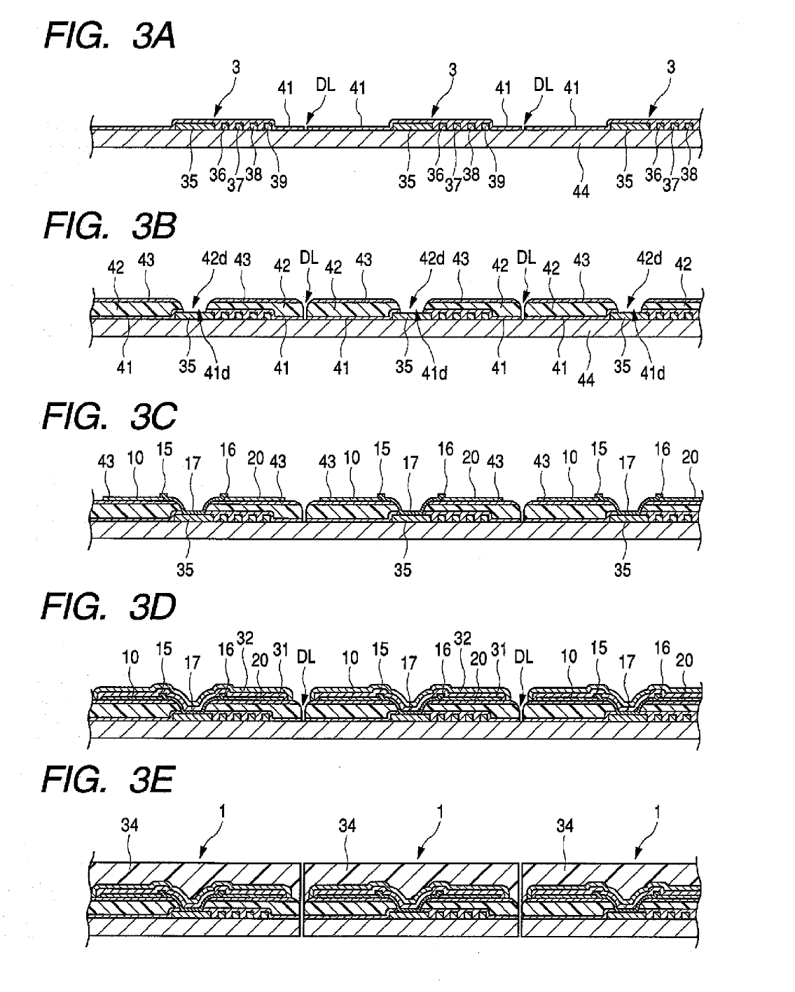

A method of manufacturing the magnetic detection device 1 according to the embodiment will be described with reference to FIGS. 3A to 3E. In a step shown in FIG. 3A, the detection circuit 3 having the plurality of groups of wiring layers 35, the active elements 36 to 38, the resistor 39, and the like, is formed on a substrate 44. That is, the detection circuit 3 is formed by performing film-forming processes, such as the chemical vapor deposition (CVD) method, the sputtering method, the coating method, and the like.

The substrate 44 is formed to have a size such that the detection circuit 3 can be formed. That is, the substrate 44 is larger than the substrate 2 of the manufactured product shown in FIGS. 1 and 2.

Sequentially, the insulating lower surface layer 41 formed of silicon nitride (SiN) on the detection circuit 60 and the substrate 44 is filmed by performing the sputtering method or the CVD method. In this case, the insulating lower surface 41 can be patterned on the detection circuit 3 and the substrate 44 other than a dicing line DL. The substrate 44 is divided into each group by the dicing line DL.

Next, in the step shown in FIG. 3B, the resistor layer 42 is coated on the insulating lower surface layer 41 by using the spin coating method or the screen printing method, and the resistor layer 42 is exposed and developed to form a hole section 42d exactly on parts of the upper surface of the wiring layer 35 at a location opposite in the layer thickness direction. The resistor layer 42 on the dicing line DL may be excluded at the time of exposing and developing the resistor layer 42. The insulating lower surface layer 41 not covered with the hole section 42d is removed by performing the etching process to expose parts of the wiring layer 35 before the resistor layer 42 becomes thermally hardened.

In the step shown in FIG. 3B, a hole section 41d is simply formed even on the insulating lower surface layer 41 by using the resistor layer 42 as a mask and etching the insulating lower surface layer 41 exposed from the hole section 42d formed on the resistor layer 42. A removal pattern is also formed on the dicing line DL by means of the above-described method. That is, the insulating lower surface layer 41 is formed on the dicing line DL to form the removal pattern on the dicing line DL of the resistor layer 42 before the insulating lower surface layer 41 exposed from the removal pattern is removed by performing the etching process.

Next, the insulating upper surface layer 43 formed of Al₂O₃, SiO₂, silicon nitride (SiN), or the like is formed on the resistor layer 42 by using the sputtering method. The insulating upper surface layer 43 can be patterned by using, for example, the lift-off resistor (not shown) such that the insulating upper surface layer 43 is not formed on the hole sections 41d and 42d and the dicing line DL. It is not required that the insulating upper surface layer 43 is formed.

Next, in a step shown in FIG. 3C, by using the film-forming technologies such as the sputtering method, the coating method, the etching method, and the like, the magnetic detection element 10 and the fixed resistance element 20 connected to the magnetic detection element 10 in series, which have the same number of the group as the detection circuit 3, are formed to have a predetermined shape on the insulating upper surface layer 43.

Additionally, the electrode layers 15, 16, 18, and 19 and the lead layer 17 shown in FIG. 1 are formed, and the lead layer 17 or the electrode layers 18 and 19 are extended to a nozzle surface of the wiring layer 35 to electrically connect a gap between the wiring layer 35 and the magnetic detection element 10 and a gap between the wiring layer 35 and the fixed resistance element 20.

The electrode layers 15, 16, 17 and 18 and the lead layer 17 can be formed of a non-magnetic conductive material by using the sputtering method and the coating method.

Next in a process shown in FIG. 3D, the magnetic detection element 10, the fixed resistance element 20, the electrode layers 15, 16, 18, and 19, and the lead layer 17 are all covered with the alumina (Al₂O₃) layer 31. The whole alumina layer 31 is covered with the silica (SiO₂) layer 32. The alumina layer 31 and the silica layer 32 can be patterned by using the sputtering method and the like not to be formed on the dicing line DL.

Next, for example, in order to generate an exchange coupling magnetic field between the antiferromagnetic layer and the fixed resistance layer included by the magnetic detection element 10, and thus fix the magnetization of the fixed resistance layer in the pin direction, the heat treatment process in a magnetic field is performed.

According to the embodiment, even when the heat treatment process is performed, the magnetic detection element 10 is covered with the alumina layer 31 having excellent thermal resistance, and thus the alumina layer 31 can properly prevent the magnetic detection element 10 from being oxidized. That is, because oxygen cannot permeate into the alumina layer 31 under a heated environment. Accordingly, the resistance value of the magnetic detection element 10 does not vary due to the oxidation, thereby preventing the characteristic degradation. Further, the fixed resistance element 20, the electrode layers 15, 16, 18, and 19, and the lead layer 17 are covered with the alumina layer 31, thereby protecting such layers from the oxidation.

According to the embodiment, even when heat treatments other than the heat treatment process for generating the exchange coupling magnetic field between the antiferromagnetic layer and the fixed resistance layer are performed, the magnetic detection element 10 can be properly prevented from being oxidized.

Next, the substrate 44 is diced along the dicing line DL to individually obtain chips.

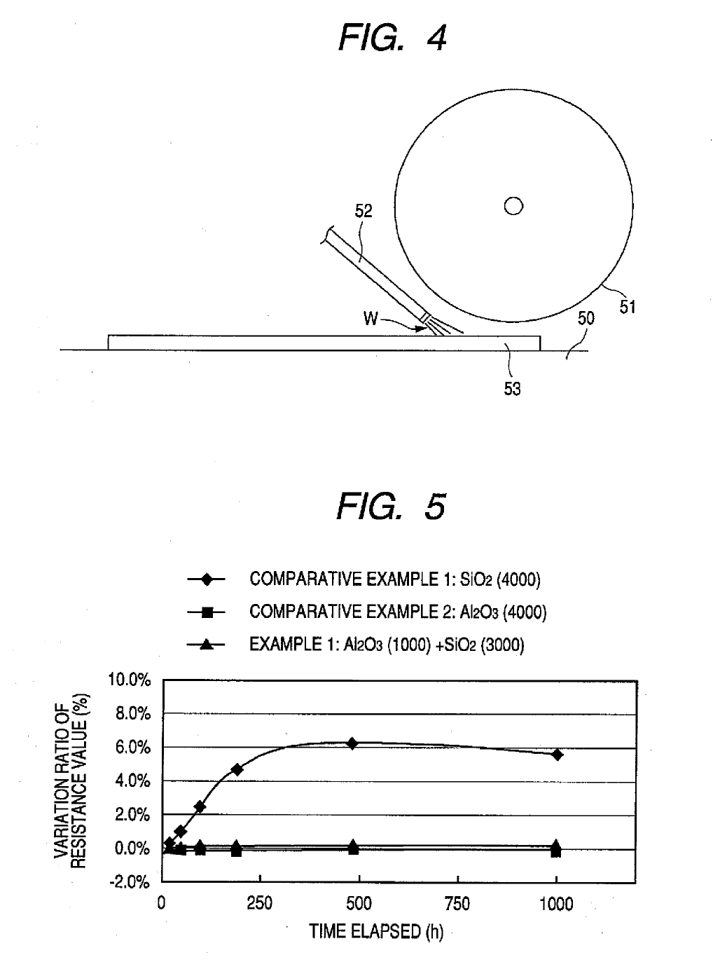

As shown in FIG. 4, on an installation support 50 is installed a magnetic detection device collective 53 having a plurality of groups of the magnetic detection devices during a manufacturing step in which the plurality of groups of the detection circuits 3 and sensor sections 4 are laminated on the substrate 44.

Additionally, the substrate 44 is cut along the dicing line DL by a dicing blade (circular blade) 51. In this case, in order to cool the frictional heat, the dicing process is performed on the magnetic detection device collective 53 while a cooling water W from the nozzle 52 is sprayed.

As shown in FIG. 3D, the uppermost layer of the magnetic detection device collective 53 is the silica layer 32, and thus the silica layer 32 is exposed. However, the silica layer 32 has good water resistance, and thus it is not eroded or dissolved even when the silica layer 32 is exposed to the cooling water W. Accordingly, the alumina layer 31 formed under the silica layer 32 is not directly exposed to water. As a result, the magnetic detection element 10 can be properly protected from moisture without eroding and dissolving the alumina layer 31 by water.

According to the embodiment, the protection structure, where the detection element is covered with the alumina layer 31 and the alumina layer 31 is covered with the silica layer 32, can properly improve both the water resistance and the thermal resistance, and can properly protect the magnetic detection element 10 from the outside environment, thereby not degrading the characteristic of the magnetic detection element 10. By covering the fixed resistance element 20, the electrode layers 15, 16, 18, and 19, and the lead layer 17 exposed in FIG. 3C, as well as the magnetic detection element 10, with the alumina layer 31 and the silica layer 32, both of the thermal resistance and the water resistance on the whole area of the sensor section 4 can be effectively improved.

In a process shown in FIG. 3E, each magnetic detection device 1 individually chipped by the dicing process is packaged by using a molded resin 34 to become a product.

Additionally, only one magnetic detection element 10 and one fixed resistance element 20 are provided according to the embodiment, but for example, by providing two magnetic detection element s10 and two fixed resistance elements 20 to configure abridge circuit, it desirable that a magnetic detection device with greater magnetic sensitivity can be realized.

Additionally, the magnetic detection element 10 and the fixed resistance element 20 are combined according to the embodiment, but for example, a magnetic detection element using another magnetic resistance effect where the pin direction is different can be configured as a circuit. Alternatively, a first magnetic detection element in which approach of the N pole of a magnet varies the resistance and the approach of the S pole thereof does not vary the resistance, and a second detection element in which the approach of the S pole of a magnet varies the resistance and the approach of the N pole thereof does not vary the resistance, can be combined to constitute a circuit.

The detection circuit 3 is formed on the substrate 2 according to the embodiment the detection circuit 3 is covered with the insulating layer 40, and the sensor section 4 is formed on the insulating layer 40. However, the sensor section 4 and the detection circuit 3 can be formed in a line in the width direction.

In such a configuration, it is preferable that the detection circuit 3 together with the sensor section 4 is covered with the insulating layer 30.

### EXAMPLE

The magnetic detection element is formed in order to perform a thermal resistance experiment with respect to each sample covering the magnetic detection element with an insulating layer shown below.

A layered configuration of the magnetic detection element used in an experiment was formed by sequentially laminating PtMn (200), CoFe (14), Ru (8.7), CoFe (12), cu (21), CoFe (10), NiFe (20), and Ta (50) from the bottom. Integers in parentheses refer to layer thicknesses and the unit is Å.

### Example 1

The magnetic detection element was covered with an alumina (Al₂O₃) layer with a thickness of 1000 Å and the alumina layer was covered with a silica (SiO₂) layer with a thickness of 3000 Å.

### Comparative Example 1

The magnetic detection element was covered with a silica (SiO₂) layer with a thickness of 4000 Å.

### Comparative Example 2

The magnetic detection element was covered with an alumina (Al₂O₃) layer with a thickness of 4000 Å.

The time elapsed and variation ratio (%) of the resistance value with respect to each sample described above were investigated while being heated at 200° C. The variation ratio (%) of the resistance value is represented as ([(resistance value after a predetermined time elapsed)−(standard resistance value)]/(standard resistance value)) 100 (%) on the basis of the standard resistance value which is a resistance value of each magnetic detection element when the time elapsed is 0 hour (that is, before a heat treatment process).

As shown in FIG. 5, the variation ratio of the resistance value was almost 0% until 1000 hours in Example 1 and Comparative Example 2 even when the heat treatment was performed, but the variation ratio of the resistance value was seen to immediately rise after the heat treatment was performed. Since the silica layer has a poor thermal resistance rather than the alumina layer, and oxygen in air permeates the silica layer in the heated environment, the magnetic detection element was oxidized and thus the resistance value rose in Comparative Example 1 in which the silica layer only was provided.

In contrast, the thicknesses of the alumina layers in Example 1 and Comparative Example 2 were different, but the variation ratio of the resistance values was almost 0%. The thickness of the alumina layer in Example 1 was 1000 Å and this thickness in Example 1 was a quarter of a thickness in Comparative Example 2, in spite of such a small thickness, a satisfactory thermal resistance could be obtained.

Next, a water resistance experiment was performed using the sample of Example 1. The result of the water resistance experiment performed under a temperature of 85° C., humidity of 85%, and time of 500 hours showed that the resistance value of the magnetic detection element rose by only 1% or so from the initial state (before the experiment of the water resistance) after the water resistance experiment was performed.

What is claimed is:

1. A magnetic detection device comprising:
a substrate;
a sensor section including a magnetic detection element using a magnetoresistance effect in which an electrical resistance varies in accordance with an exterior magnetic field; and
a detection circuit connected to the sensor section to detect a variation in potential based on the variation in the electrical resistance of the magnetic detection element the sensor section and the detection circuit being formed on the substrate,
wherein the magnetic detection element is covered with an insulating protection layer which has an alumina layer (Al₂O₃) covering the magnetic detection element, and a silica layer (SiO₂) covering the alumina layer.

2. The magnetic detection device according to claim 1,
wherein the sensor section is connected in series to the magnetic detection element and has a fixed resistance element in which the electrical resistance does not vary in accordance with the exterior magnetic field; and
wherein the fixed resistance element is covered with the insulating protection layer.

3. The magnetic detection device according to claim 1, wherein the insulating protection layer covers a conductive connection layer which connects the magnetic detection element and/or the fixed resistance element to the detection circuit.

4. The magnetic detection device according to claim 1,
wherein the detection circuit is formed on the substrate, the detection circuit is covered with an insulating layer, and the sensor section is formed on the insulating layer; and
wherein the sensor section on the insulating layer and the detection circuit on the substrate are conductively connected to each other.

5. A method of manufacturing a magnetic detection device which has a sensor section includes a magnetic detection element using a magnetoresistance effect in which an electrical resistance varies in accordance with an exterior magnetic field, and the detection circuit is connected to the sensor section to detect a variation in potential based on the variation in the electrical resistance of the magnetic detection element formed on the substrate, the method comprising the steps of:
(a) forming a plurality of groups of the detection circuits and the sensor sections on the substrate;
(b) covering the magnetic detection elements with an alumina (Al₂O₃) layer and covering the alumina layer with a silica (SiO₂) layer;
(c) dicing the substrate into groups where the silica layer is exposed, while spraying cooling water, thereby obtaining individual chips of the magnetic detection device; and
(d) packaging each of the chips of the magnetic detection devices.

6. The method of manufacturing the magnetic detection device according to claim 5, wherein the step of (a) includes:
(a-1) forming the plurality of groups of the detection circuits on the substrate;
(a-2) covering the detection circuits with an insulating layer; and
(a-3) forming the plurality of groups of the sensor section on the insulating layer to conductively connect each sensor section and each detection circuit to each other.

7. The method of manufacturing the magnetic detection device according to claim 5,
wherein the sensor section is connected in series to the magnetic detection element and has a fixed resistance element in which an electrical resistance does not vary in accordance with an exterior magnetic field; and
wherein the fixed resistance element is covered with the alumina layer and the alumina layer is covered with the silica layer in the step of (b).

8. The method of manufacturing the magnetic detection device according to claim 5, wherein a conductive connection layer which connects the magnetic detection element and/or the fixed resistance element to the detection circuit is covered with the alumina layer, and the alumina layer is covered with the silica layer in the step of (b).
